(19) United States
(12) Patent Application Publication
(10) Pub. No.: US 2025/0348377 A1
(43) Pub. Date: Nov. 13, 2025

(54) METHOD FOR REPAIRING A ONE-TIME PROGRAMMABLE MEMORY

(71) Applicant: STMicroelectronics International N.V., Geneva (CH)

(72) Inventors: Philippe GENDRIER, Grenoble (FR); Baptiste GRATUZE, Grenoble (FR); Marco CASARSA, Milano (IT)

(73) Assignee: STMicroelectronics International N.V., Geneva (CH)

(21) Appl. No.: 19/199,968

(22) Filed: May 6, 2025

(30) Foreign Application Priority Data
May 7, 2024 (FR) FR2404798

(51) Int. Cl. G06F 11/10

(52) U.S. Cl. CPC G06F 11/1048

(57) ABSTRACT

A one-time programmable memory includes memory locations that are each identified by an address, where each memory location is configured to store a digital data having a given number of bits. The memory locations are arranged into a first memory zone, a second memory zone, and a third memory zone. A method for controlling the one-time programmable memory includes: determining that a read operation of a digital data in a first memory location of the first memory zone has failed, and in response thereto writing the digital data in a second memory location of the second memory zone and writing, in a third memory location of the third memory zone, the address of the first memory location and an identifier of the second memory location.

### PRIORITY CLAIM

This application claims the priority benefit of French Application for Patent No. FR2404798, filed on May 7, 2024, the content of which is hereby incorporated by reference in its entirety to the maximum extent allowable by law.

### TECHNICAL FIELD

The present description relates generally to methods for repairing a one-time programmable memory.

### BACKGROUND

A non-volatile memory is a memory comprising memory cells wherein bits of a digital signal are stored, being used to store information that should not be lost as the memory is no longer powered. A One-Time Programmable (OTP) memory is a type of memory programmable only once.

During the manufacturing of a memory, particularly a one-time programmable memory, some memory cells could be not operational. To be able, however, to use the memory, it is known to implement methods for correcting errors during the storage of the digital signal, which allows a limited number of corrupted bits to be corrected.

With the current trend to reduce the size of the memory cells in one-time programmable memories, the number of defective memory cells can increase, and implementing error correction methods could be insufficient to compensate a high number of defective memory cells. In addition, implementing error correction methods to operate the memory upon a test after manufacturing reduces the robustness of memories in applications. In some cases, the reliability constraints may requisite not to implement the error correction methods to operate the memory upon the test, and only means for repairing may allow the manufacturing yield to be increased.

There is a need in the art to overcome all or part of the drawbacks of known one-time programmable memories.

### SUMMARY

One embodiment provides a method for controlling a one-time programmable memory comprising memory locations that are each identified by an address, each memory location being configured to store a digital data having a given number of bits, the memory locations being arranged into a first memory zone, a second memory zone, and a third memory zone, the method comprising, when a read operation of a digital data in a first memory location of the first memory zone has failed, writing the digital data in a second memory location of the second memory zone, and writing in a third memory location of the third memory zone the address of the first memory location and an identifier of the second memory location.

According to an embodiment, the identifier of the second memory location is equal to the address of the second memory location.

According to an embodiment, the memory locations of the second memory zone are arranged into first groups GW_j, j ranging from 1 to N, comprising each NA consecutive memory locations of the second memory zone, the memory locations of the third memory zone are arranged into second groups GADD_i, i ranging from 1 to N, comprising each NA consecutive memory locations of the third memory zone, the second memory location is located in the first group GW_k, k being an integer ranging from 1 to N, and the third memory location is located in the second group GADD_k.

According to an embodiment, the identifier of the second memory location is equal to the rank of the second memory location in the first group GW_k.

According to an embodiment, the rank is coded over a number of bits less than, or equal to, 4.

According to an embodiment, the number NA ranges from 2 to 16.

According to an embodiment, writing the digital data in the second memory location is performed in one of the first groups GW_j, j ranging from 1 to N, and no write operation was already performed in each of the memory locations of said group.

According to an embodiment, the method comprises, when writing the digital data in the second memory location fails, writing the digital data in a next second memory location of the second memory zone, and comprises, when writing the address of the first memory location in the third memory location fails, writing the address of the first memory location in a next third memory location of the third memory zone.

According to an embodiment, starting-up the one-time programmable memory comprises reading the second memory zone, and when the second memory zone is not empty, copying in a further memory, for each operation of writing a digital data in the first memory location of the first memory zone having failed, the address of the first memory location and the address of the third memory location.

According to an embodiment, a read operation in the first memory zone of the one-time programmable memory comprises providing an address, searching the provided address in the further memory, in the case where the provided address is not present in the further memory, reading the digital data stored in the memory location of the first memory zone at the provided address, and in the case where the provided address is present in the further memory, reading the digital data stored in the third memory location of the second memory zone.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates schematically an embodiment of a one-time programmable memory;

FIG. 2 is a block diagram of an embodiment of a method for repairing the one-time programmable memory shown in FIG. 1;

FIG. 3 is a block diagram of an embodiment of a method for starting the one-time programmable memory shown in FIG. 1 up;

FIG. 4 is a block diagram of an embodiment of a method for reading the one-time programmable memory shown in FIG. 1;

FIG. 5 illustrates schematically another embodiment of a one-time programmable memory;

FIG. 6 is a block diagram of an embodiment of a method for repairing the one-time programmable memory shown in FIG. 5;

FIG. 7 is a block diagram of an embodiment of a method for starting the one-time programmable memory shown in FIG. 5 up; and

FIG. 8 is a block diagram of an embodiment of a method for reading the one-time programmable memory shown in FIG. 5.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, those skilled in the art knows the technologies of a one-time programmable memory, and are not described.

Unless specified otherwise, the expressions “around”, “approximately”, “substantially” and “in the order of” signify within 10% or within 10°, and preferably within 5% or within 10°.

According to one embodiment, the method for repairing an OTP memory comprises, when an operation of writing a digital data at a first location in the OTP memory is not possible, writing the digital data at another location in the OTP memory, and writing the address of the first location also in another location in the OTP memory. Advantageously, the structure of the OTP memory cannot be modified to implement the repair method. This advantageously allows the repair method to be implemented with any type of OTP memory. Further, the fact of writing the (repaired) digital data and the first location address in different locations advantageously allows the chance of not being able to perform the repair to be reduced. Advantageously, the probability that the repair method is successfully performed is thus increased. The repair method takes into account the same failure probability as in a normal write operation in the OTP memory. Advantageously the repair method thus has the same robustness as that during a normal operation of the OTP memory. Advantageously the repair method further could implement the same correction technics as that implemented during a normal operation of the OTP memory.

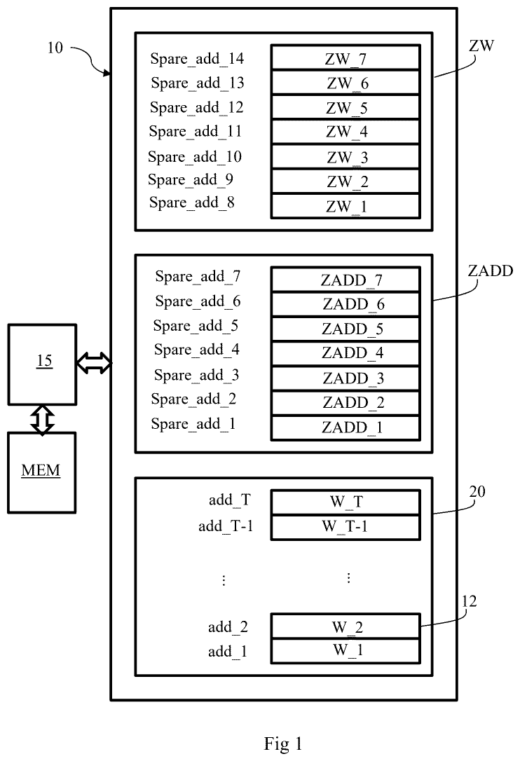

FIG. 1 illustrates schematically an embodiment of an OTP memory 10 configured to implement a repair method. OTP memory 10 comprises memory locations 12. A digital signal having a determined number Nb_W of bits (e.g., 32 bits) can be stored in each memory location 12. The position of each memory location 12 in memory 10 is identified by an address. A memory location address is coded over a number Nb_Add of bits. The number Nb_Add is generally less than number Nb_W. As an example, number Nb_Add is equal to 8 bits. An electronic circuit 15 for controlling memory 10 is configured to perform a write or read operation in memory 10. According to one embodiment, several write operations can be implemented in the OTP memory 10. By contrast, it is not possible to erase a previously written data. A write operation in the OTP memory 10 by the control circuit 15 comprises providing an address and a digital signal by the control circuit 15 to the OTP memory 10, and storing the digital signal stored in the memory location 12 corresponding to this address. A read operation in the OTP memory 10 by the control circuit 15 comprises providing by the control circuit 15 to the OTP memory 10 an address, the OTP memory 10 providing then the digital signal stored in the memory location 12 at this address. According to the one-time programmable memory technology implemented, a read operation in a memory location in which no write operation was performed returns bits with all the logic value “0”, or all the logic value “1”.

According to one embodiment, the memory locations 12 of the OTP memory 10 are organized into a first memory zone 20, designed in the following as main memory zone, a second memory zone ZW, designed in the following as data repair memory zone, and a third memory zone ZADD, designed in the following as address repair memory zone. The main memory zone 20 is used for storing data during an error-free operation of memory location 12. The main memory zone 20 comprises a number T of memory locations W_k with addresses add_k, k being an integer ranging from 1 to T. The address and data repair memory zones ZADD and ZW are used to perform a repair operation. The address repair memory zone ZADD comprises a number NT of memory locations ZADD_i having addresses Spare_add_i, i being an integer ranging from 1 to NT. The repair data memory zone ZW comprises the number NT of memory locations ZW_j, having addresses Spare_add_NT+j, j being an integer ranging from 1 to NT. As an example, in FIG. 1, NT is equal to 7, and, for the address and data repair memory zones ZADD and ZW, each address is indicated next to the corresponding memory location. According to one embodiment, the memory location addresses of the address repair memory zones ZADD and the memory location addresses of the data repair memory zone ZW are in sequence. This would mean that an address is equal to the sum of the preceding address and the digit “1”. The address Spare_add_1 is designed as first address of the address repair memory zone ZADD, and the address Spare_add_NT is designed as last address of the address repair memory zone ZADD. Similarly, the address Spare_add_NT+1 is designed as first address of the data repair memory zone ZW, and the address Spare_add_2NT is designed as last address of the data repair memory zone ZW.

According to one embodiment, in each memory location ZW_j of the data repair memory zone ZW, a word can be stored, which could not be stored in a memory location 12 of the main memory zone 20, designed in the following as defective location. According to one embodiment, in each memory location ZADD_i of the address repair memory zone ZADD, can be stored the address add_k of the defective location W_k of the main memory zone 20, and the address of the memory location ZW_j of the data repair memory zone ZW in which is stored the word that should have been stored in the defective location. According to one embodiment, in each memory location ZADD_i of the address repair memory zone ZADD, could further be stored one or more bits provided by an error correction method. According to one embodiment, in each memory location ZADD_i of the address repair memory zone ZADD may further be stored at least one validity bit indicating that the write operation in the memory location ZADD_i occurred without error. The data stored in the memory location ZADD_i of the address repair memory zone ZADD are in the following designed as address parameters.

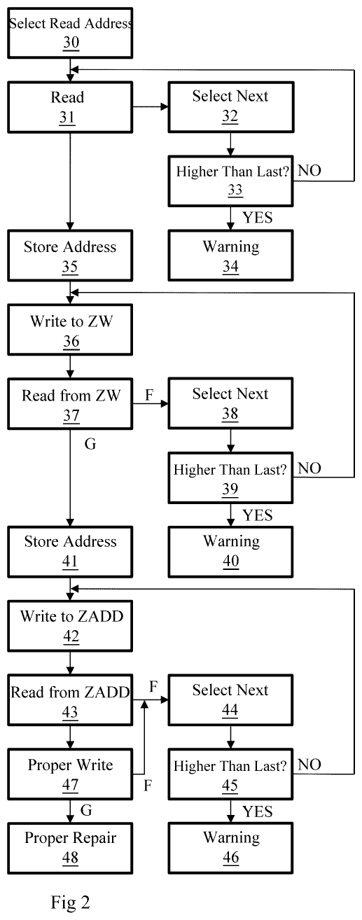

FIG. 2 is a block diagram of an embodiment of a method for repairing the OTP memory 10 shown in FIG. 1.

In step 30, the control circuit 15 selects the read address at value Spare_add_NT+1 (i.e., at the first address of the data repair memory zone ZW). The method goes on in step 31.

In step 31, the control circuit 15 performs a reading in the data repair memory zone ZW at the memory location at the selected address. If the read data differ from the value expected in the absence of read operation, it means that the memory location of the data repair memory zone ZW at the selected address is not available, and the method goes on in step 32.

In step 32, the control circuit 15 selects the next address of the data repair memory zone ZW. The method goes on in step 33.

In step 33, the control circuit 15 determines whether the selected address is higher than the last address Spare_Add_2NT of the data repair memory zone ZW. If the selected address is less than, or equal to, the last address of the data repair memory zone ZW (No), the method goes on in step 31. If the selected address is higher than the last address of the data repair memory zone ZW (Yes), it means that no memory location of the data repair memory zone ZW is available, the method goes on in step 34.

In step 34, the control circuit 15 delivers a warning signal indicating that the repair operation failed.

In step 31, if the read data during the read operation are equal to the expected value in the absence of read operation, the method goes on in step 35.

In step 35, the control circuit 15 stores the address Spare_add_NT+j of the memory location ZW_j of the data repair memory zone ZW available to perform a repair operation, the method goes on in step 36.

In steps 36 to 40, the control circuit 15 of memory 10 writes the digital data to be repaired in the data repair memory zone ZW.

In step 36, the control circuit 15 performs a write operation of the digital data to be repaired in the available memory location of the data repair memory zone ZW at the selected address. The method goes on in step 37.

In step 37, the control circuit 15 performs a reading in the data repair memory zone ZW at the memory location at the selected address. If the reading step fails (F), the method goes on in step 38.

In step 38, the control circuit 15 selects the next address of the data repair memory zone ZW. The method goes on in step 39.

In step 39, the control circuit 15 determines whether the next selected address is higher than the last address of the data repair memory zone ZW. If the new selected address is less than, or equal to, the last address of the data repair memory zone ZW (No), the method goes on in step 36. If the new selected address is higher than the last address of the data repair memory zone ZW Yes), it means that there is no more memory location available in the data repair memory zone ZW, and the method goes on in step 40.

In step 40, the control circuit 15 delivers a warning signal indicating that the repair operation failed.

In step 37, if the read operation runs properly (G), the method goes on in step 41.

In steps 41 to 48, the control circuit 15 of memory 10 writes the parameters of the address of the digital data to be repaired in the first repair memory zone ZADD.

In step 41, the control circuit 15 selects the address of the first repair memory ZADD, which has the same gap as compared to the first address of the first repair memory ZADD as the gap of the memory location address available of the data repair memory zone ZW as compared to the first address of the data repair memory zone W. As an example, when the available memory location address of the data repair memory zone ZW is, in binary coding over 8 bits, in the form of 001xxxxx, the selected address of the memory location of the first repair memory ZADD can be in the form 000xxxxx. The method goes on in step 42.

In step 42, the control circuit 15 performs a write operation of the address parameters in the memory location of the first repair memory ZADD at the selected address. The method goes on in step 43.

In step 43, the control circuit 15 performs a read operation in the first repair memory ZADD at the memory location at the selected address. If the reading step fails (F), the method goes on in step 44.

In step 44, the control circuit 15 selects the next address of the first repair memory zone ZADD. The method goes on in step 45.

In step 45, the control circuit 15 determines whether the new selected address is higher than the last address of the address repair memory zone ZADD. If the new selected address is less than, or equal to, the last address of the address repair memory zone ZADD (No), the method goes on in step 42. If the new selected address is higher than the last address of the address repair memory zone ZADD (Yes), it means that no more memory location of the first repair memory zone ZW is available, and the method goes on in step 46.

In step 46, the control circuit 15 delivers a warning signal indicating that the repair operation failed.

In step 43, if the read operation runs properly (G), the method goes on in step 47.

In step 47, the control circuit 15 checks that the address parameters were properly written. This may comprises checking the validity bit of the address parameters. If the validity-checking operation fails (F), the method goes on in step 44. If the validity-checking operation succeeds (G), the method goes on in step 48.

In step 48, the control circuit 15 indicates that the repair operation ran properly.

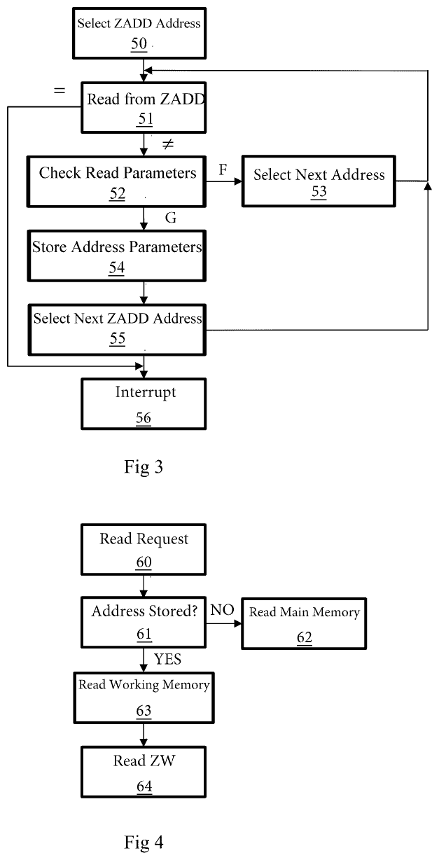

FIG. 3 is a block diagram of an embodiment of a method for starting the memory 10 up.

The control circuit 15 determines whether repair operations occurred. To this end, it performs a read operation in the address repair memory zone ZADD.

In step 50, the control circuit 15 selects the first address Spare_add_1 of the address repair memory zone ZADD. The method goes on in step 51.

In step 51, the control circuit 15 performs a reading in the first repair memory zone ZADD at the memory location at the selected address. If the read digital data are equal to the expected value in the absence of write operation (=), it means that there has been no repair operation, and the method goes on in step 56. If the read digital data differ from the expected value in the absence of write operation (≠), it means that there has been at least one repair operation, and the method goes on in step 52.

In step 52, the control circuit 15 checks that the read address parameters are correct. This may comprises checking the validity bit of the address parameters. If the validity-checking operation fails (F), the method goes on in step 53. If the validity-checking operation succeeds (G), the method goes on in step 54.

In step 53, the control circuit 15 selects the next address of the first repair memory ZADD. The method goes on in step 51.

In step 54, the control circuit 15 stores in a working memory MEM, different from the OTP memory, for example a RAM, from the address parameters, the defective location address of the main memory zone 20 that was repaired, and the address of the data repair memory zone ZW where are stored the digital data that should have been stored in the defective location. The method goes on in step 55.

In step 55, the control circuit 15 selects the next address of the first repair memory ZADD. If the new selected address is less than, or equal to, the last address of the address repair memory zone ZADD, the method goes on in step 51. If the new selected address is higher than the last address of the address repair memory zone ZADD, the method goes on in step 56.

In step 56, the starting-up method is interrupted.

FIG. 4 is a block diagram of an embodiment of a method for reading in the memory 10.

In step 60, the control circuit 15 receives a read request with an address of the main memory zone 20 of the memory 10. The method goes on in step 61.

In step 61, the control circuit 15 determines whether the read address is a part of the addresses stored in the working memory MEM used during the starting-up of the memory 10. If the address is not a part of the addresses stored in the working memory MEM (No), the method goes on in step 62. If the address is a part of the addresses stored in the working memory MEM (Yes), the method goes on in step 63.

In step 62, the control circuit 15 performs an operation of reading in the main memory zone 20 of the memory 10 at the address received at step 60.

In step 63, the control circuit 15 reads in the working memory MEM the address of the data repair memory zone ZW in the working memory MEM associated with the requested address.

In step 64, the control circuit 15 performs a read operation in the data repair memory zone ZW of the memory 10 with the address retrieved in step 63.

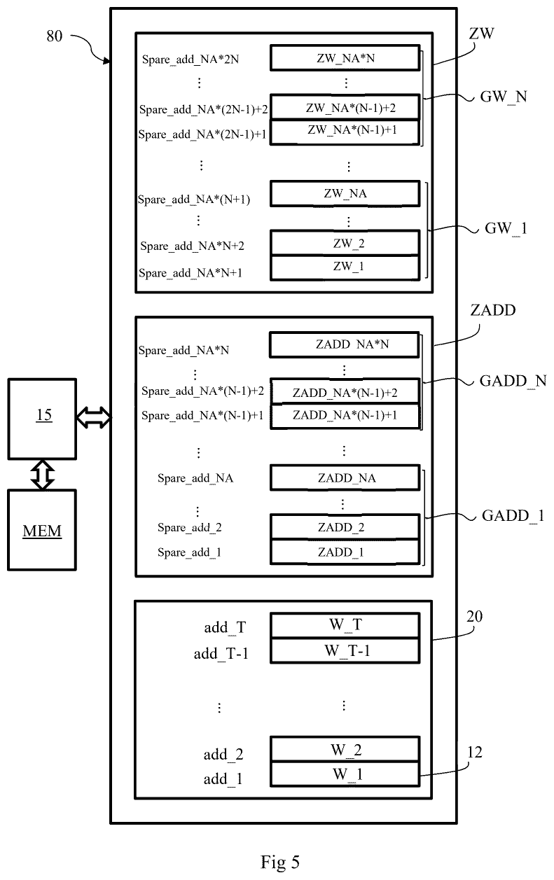

FIG. 5 illustrates schematically another embodiment of an OTP memory 80 adapted to implement a repair method. The OTP memory 80 comprises all the elements of the OTP memory 10 with the differences that the T memory locations of the address repair memory zone ZADD are arranged in N groups GADD_i of NA memory locations each, i ranging from 1 to N, and that the T memory locations of the data repair memory zone ZW are arranged in N groups GW_j of NA memory locations each, j ranging from 1 to N. According to one embodiment, the number NA is higher than, or equal to 2, and preferably ranges from 2 to 16, more preferably from 2 to 10. The number NA particularly depends on a failure rate of the OTP memory 80, and on the objectives of necessary repairs. Are illustrated the first group GADD_1 of memory locations ZADD_1, ZADD_2, . . . , ZADD_NA of the address repair memory zone ZADD, and the N^{th} group GADD_N of memory locations ZADD_NA*(N−1)+1, ZADD_NA*(N−1)+2, . . . , and ZADD_NA*N of the address repair memory zone ZADD, and are illustrated the first group GW_1 of memory locations ZW_1, ZW_2, and ZW_NA of the data repair memory zone ZW, and the N^{th} group GW_N of memory locations ZW_NA*(N−1)+1, ZW_NA*(N−1)+2, . . . , ZW_NA*N of the data repair memory zone ZW.

According to one embodiment, the addresses of the memory locations of the address repair memory zone ZADD, and the memory locations of the data repair memory zone ZW are consecutive. The addresses of the NA first memory locations of the address repair memory zone ZADD are Spare_add_1, Spare_add_2, . . . , Spare_add_NA, and the addresses of the NA last memory locations of the address repair memory zone ZADD are Spare_add_NA*(N−1)+1, Spare_add_NA*(N−1)+2, . . . , Spare_add_NA*N. The addresses of the 4 first memory locations of the data repair memory zone ZW are Spare_add_NA*N+1, Spare_add_NA*N+2, . . . , Spare_add_5 NA*(N+1), and the addresses of the NA last memory locations of the data repair memory zone ZW are Spare_add_NA*(2N−1)+1, Spare_add_NA*(2N−1)+2, . . . , Spare_add_NA*2N.

According to one embodiment, for the memory 80, the total number of repairs that could be performed is equal to N. For each repair, the maximum number of attempts to perform the repair is equal to NA. Each group GW_i, i ranging from 1 to N, of NA memory locations of the data repair memory zone ZW is associated with the group GADD_i of NA memory locations of the address repair memory zone ZADD.

As previously described as regards the OTP memory 10, at each memory location ZW_j, j ranging from 1 to NA*N, of the data repair memory zone ZW of the OTP memory 80 can be stored a digital data which could not be stored in a defective memory location W_k, k ranging from 1 to T, of the main memory zone 20. However, according to one embodiment, the address parameters stored in the memory locations ZADD_i, i ranging from 1 to NA*N, of the address repair memory zone ZADD of the OTP memory 80 differ from the address parameters stored in the memory locations ZADD_i of the address repair memory zone ZADD of the OTP memory 10.

According to one embodiment, unlike that was previously described as regards the OTP memory 10, in each memory location ZADD_i of the address repair memory zone ZADD of the OTP memory 80 can be stored the address add_k of the defective location W_k of the main memory location 20, and the rank between 1 and NA of the address Spare_add_j, j ranging from NA*N+1 to NA*2N, of the memory location ZW_j of the data repair memory zone ZW in which were stored the digital data which could not be stored in the defective location W_k of the main memory location 20. According to one embodiment, in each memory location ZADD_i of the address repair memory zone ZADD can further be stored one or more bits provided by an error correction method. According to one embodiment, in each memory location ZADD_i of the address repair memory zone ZADD can further be stored at least one validity bit indicating that the write operation in the memory location ZADD_i occurred without error.

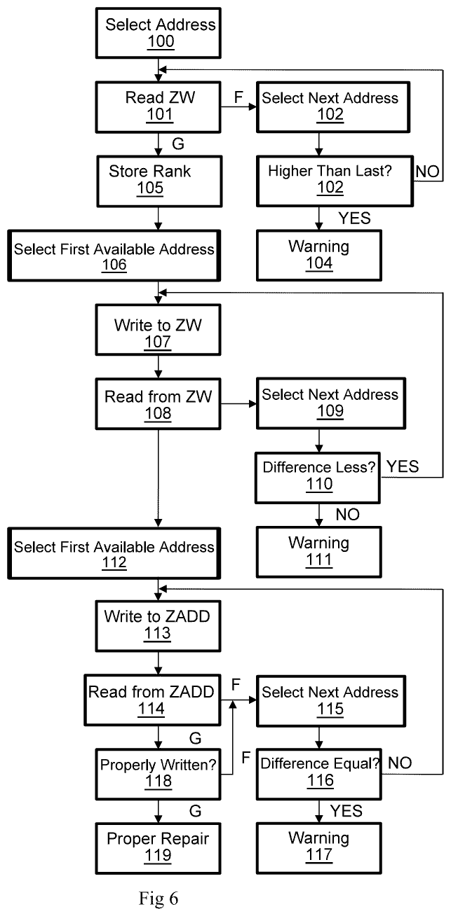

FIG. 6 is a block diagram of an embodiment of a method for repairing the OTP memory 80.

In steps 100 to 105, the control circuit 15 of the OTP memory 80 determines whether there is an available memory location in the data repair memory zone ZW.

In step 100, the control circuit 15 selects the address at value Spare_add_4N+1 (i.e., the first address of the data repair memory zone ZW). The method goes on in step 101.

In step 101, the control circuit 15 performs a reading in the data repair memory zone ZW at the memory location at the selected address. If the read data differ from the expected value in the absence of write operation (F), it means that the memory location of the data repair memory zone ZW at the selected address is not available, and the method goes on in step 102.

In step 102, the control circuit 15 selects the next address of the data repair memory zone ZW. The method goes on in step 103.

In steps 103, the control circuit 15 determines whether the selected address is higher than the last address Spare_add_NA*2N of the data repair memory zone ZW. If the selected address is less than, or equal to, the last address of the data repair memory zone ZW (No), the method goes on in step 101. If the selected address is higher than the last address of the data repair memory zone ZW (Yes), it means that no memory location of the data repair memory zone ZW is available, the method goes on in step 104.

In step 104, the control circuit 15 delivers a warning signal indicating that the repair operation failed.

In step 101, if the data read during the read operation are equal to the expected value in the absence of write operation for the four addresses of the group (G), the method goes on in step 105.

In the step 105, the control circuit 15 stores the rank of the memory location ZW_j of the data repair memory zone ZW available to perform a repair operation. As an example, when the available memory location address of the data repair memory zone ZW is, in binary coding over 8 bits, in the form of 001rrrxx, where rrr codes the suffix i of the group GW_i to which the memory location ZW_j belongs when N is equal to 8, and where xx codes the rank of the memory location ZW_j when NA is equal to 4. The method goes on in step 106.

In steps 106 to 111, the control circuit 15 of the memory 80 writes the digital data to be repaired in the data repair memory zone ZW.

In step 106, the control circuit 15 selects the address of the first memory location of the group in which the NA memory locations are available. As an example, the selected address of the first location memory of a group GW_i of available memory locations of the data repair memory zone ZW is, in binary coding over 8 bits, in the form 001rrr00, where rrr codes the suffix i of the group GW_i. The method goes on in step 107.

In step 107, the control circuit 15 performs a write operation of the digital data to be repaired in the available memory location of the data repair memory zone ZW at the selected address. The method goes on in step 108.

In step 108, the control circuit 15 performs a reading in the data repair memory zone ZW at the memory location of the selected address. If the reading step fails (F), the method goes on in step 109.

In step 109, the control circuit 15 selects the next address of the data repair memory zone ZW. The method goes on in step 110.

In step 110, the control circuit 15 determines whether the difference between the new selected address and the first-selected address during the first writing attempt is equal to NA. If the difference between the new selected address and the first-selected address during the first writing attempt is less than NA, the method goes on in step 107. If the difference between the new selected address and the first-selected address during the first writing attempt is less than NA, it means that none of the NA memory locations of the group of the data repair memory zone ZW is available, and the method goes on in step 111.

In step 111, the control circuit 15 delivers a warning signal indicating that the repair operation failed.

In step 108, if the read operation runs properly, the method goes on in step 112.

In steps 112 to 119, the control circuit 15 of memory 80 writes the address parameters of the digital data to be repaired in the address repair memory zone ZADD.

In step 112, the control circuit 15 selects the address of the first memory location of the group of the address repair memory zone ZADD associated with the group of the data repair memory zone ZW in which the repaired digital data were written. As an example, when the address of the first memory location of the group GW_i of memory locations of the data repair memory zone ZW in which the repaired digital data were written is, in binary coding over 8 bits, in the form of 001rrr00, where rrr codes the suffix i of the group GW_i, the address of the first memory location of the group GADD_i of the address repair memory zone ZADD that is associated to the group of the data repair memory zone ZW in which the repaired digital data were written, can be in the form 000rrr00. The method goes on in step 113.

In step 113, the control circuit 15 performs a write operation of the address parameters in the memory location of the address repair memory zone ZADD at the selected address. The method goes on in step 114.

In step 114, the control circuit 15 performs a reading in the address repair memory zone ZADD at the memory location of the selected address. If the reading step fails (F), the method goes on in step 115.

In step 115, the control circuit 15 selects the next address of the address repair memory zone ZADD. The method goes on in step 116.

In step 116, the control circuit 15 determines whether the difference between the new selected address and the first-selected address during the first writing attempt is equal to NA. If the difference between the new selected address and the first-selected address during the first writing attempt is less than NA (No), the method goes on in step 113. If the difference between the new selected address and the first-selected address during the first writing attempt is equal to NA (Yes), it means that none of the NA memory locations of the group of the address repair memory zone ZADD is available, the method goes on in step 117.

In step 117, the control circuit 15 delivers a warning signal indicating that the repair operation failed.

In step 114, if the read operation runs properly (G), the method goes on in step 118.

In step 118, the control circuit 15 checks that the address parameters were properly written. It may comprises checking the validity bit of the address parameters. If the validity-checking operation fails (F), the method goes on in step 115. If the validity-checking operation succeeds (G), the method goes on in step 119.

In step 119, the control circuit 15 indicates that the repair operation properly ran.

The embodiment of the repair method previously described in relation to FIG. 6 advantageously allows the bit number necessary to designate the memory location of the data repair memory zone ZW. Indeed, the rank may be coded over a reduced number of bits, preferably over less than four bits, for example over two or three bits, according to the number NA of repair attempts.

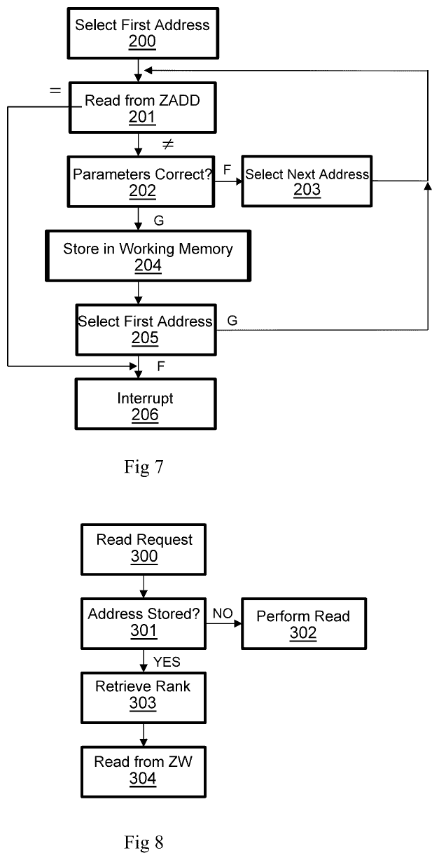

FIG. 7 is a block diagram of an embodiment of a method for starting the memory 80 up.

The control circuit 15 determines whether the repair operations occurred. To this end, it performs a read operation in the address repair memory zone ZADD.

In step 200, the control circuit 15 selects the first address Spare_add_1 of the address repair memory zone ZADD. The method goes on in step 201.

In step 201, the control circuit 15 performs a reading in the address repair memory zone ZADD at the memory location at the selected address. If the read digital data are equal to the expected value in the absence of write operation, it means that there was no repair operation, and the method goes on in step 206. If the read digital data differ from the expected value in the absence of write operation, it means that there was at least one repair operation, and the method goes on in step 202.

In step 202, the control circuit 15 checks that the read address parameters are correct. This may comprises checking the validity bit of the address parameters. If the validity-checking operation fails (F), the method goes on in step 203. If the validity-checking operation succeeds (G), the method goes on in step 204.

In step 203, the control circuit 15 selects the next address of the address repair memory zone ZADD. The method goes on in step 201.

In step 204, the control circuit 15 stores in a working memory MEM, different from the OTP memory, for example a RAM memory, from the address parameters, the defective location address of the main memory zone 20 that were repaired and the rank. Since the data consecutively stored in the working memory MEM, data (the address of the defective location address of the main memory zone 20 that was repaired and the rank) stored in the kth memory location of the working memory MEM means that the repair was performed in the group GW_k of the data repair memory zone ZW, and in the group GADD_k of the address repair memory zone ZADD. According to one embodiment, the control circuit 15 stores in a working memory MEM, different from the OTP memory, for example a RAM, from the address parameters, the address of the defective location of the main memory zone 20 that was repaired, and the memory location address of the address repair memory zone ZADD used for repairing. The method goes on in step 205.

In step 205, the control circuit 15 selects the first address of the next group of the address repair memory zone ZADD, and if the address is available (G). The method goes on in step 201. In step 205, if there is no more next group of the address repair memory zone ZADD (F), the method goes on in step 206.

In step 206, the starting-up method is interrupted.

FIG. 8 is a block diagram of an embodiment of a method for reading the memory 80.

In step 300, the control circuit 15 receives a reading request with a reading address of the main memory zone 20 of the memory 80. The method goes on in step 301.

In step 301, the control circuit 15 determines whether the reading address is a part of reading addresses stored in the working memory MEM used during the starting-up of memory 80. If the address is not a part of the addresses stored in the working memory MEM (N), the method goes on in step 302. If the address is a part of the addresses stored in the working memory MEM (Y), the method goes on in step 303.

In step 302, the control circuit 15 performs a read operation in the main memory zone 20 of memory 80 at the address received in step 300.

In step 303, the control circuit 15 retrieves the rank of the data repair memory zone ZW, and determines a corrected address. The method goes on in step 304.

In step 304, the control circuit 15 performs a read operation in the data repair memory zone ZW of memory 80 at the corrected address.

The device is, for example, intended to automotive industry. Electrifying automotive vehicles generates a high and increasing level of electronics content in the vehicles. Automating of driving also generates a high and increasing level of electronics content in the vehicles.

The device may, for example, be used in the industrial field. More particularly, the device aims, for example, to be used for developing green energy, or to electrify infrastructures, for example for charge posts, or for incorporating solar energy. The apparatus may also be used in the Internet of Things and smart house fields. The apparatus may also be used in implementing cloud, 5G networks, data centers, and servers.

The device is, for example, intended to be used in personal electronics, in 5G connecting apparatus, or more generally in connected apparatus. The apparatus is, for example, a smartphone, or a part of an Internet of Things network.

The device is for example intended to be used in communications equipment, or in computers, and peripherals. For example, the apparatus may be used in a 5G infrastructure, and in dedicated data centers. The device may also be used in satellites.

However, it is evident that the previously described applications are indicated only as an example, and that other applications may be considered.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A method for controlling a one-time programmable memory that includes memory locations that are each identified by an address, each memory location configured to store a digital data having a given number of bits, wherein the memory locations are arranged in a first memory zone, a second memory zone, and a third memory zone, the method comprising:
in response to a failure of a read operation of digital data in a first memory location of the first memory zone:
writing the digital data in a second memory location of the second memory zone; and
writing, in a third memory location of the third memory zone, the address of the first memory location and an identifier of the second memory location.

2. The method according to claim 1, wherein the identifier of the second memory location is equal to the address of the second memory location.

3. The method according to claim 1, wherein the memory locations of the second memory zone are arranged into first groups GW_j, j ranging from 1 to N, comprising each NA consecutive memory locations of the second memory zone, wherein the memory locations of the third memory zone are arranged into second groups GADD_i, i ranging from 1 to N, comprising each NA consecutive memory locations of the third memory zone, wherein the second memory location is located in the first group GW_k, k being an integer ranging from 1 to N, and wherein the third memory location is located in the second group GADD_k.

4. The method according to claim 3, wherein the identifier of the second memory location is equal to a rank of the second memory location in the first group GW_k.

5. The method according to claim 4, wherein the rank is coded over a number of bits less than, or equal to, 4.

6. The method according to claim 3, wherein the number NA ranges from 2 to 16.

7. The method according to claim 3, wherein writing the digital data in the second memory location is performed in one of the first groups GW_j, j ranging from 1 to N, and wherein no write operation was already performed in each of the memory locations of said group.

8. The method according to claim 1, comprising, in response to failure to write the digital data in the second memory location, writing the digital data in a next second memory location of the second memory zone, and comprising, in response to failure to write the address of the first memory location in the third memory location, writing the address of the first memory location in the a third memory location of the third memory zone.

9. The method according to claim 1, wherein starting-up the one-time programmable memory comprises:
reading the second memory zone; and
when the second memory zone is not empty: copying in a further memory, for each operation of writing a digital data in a first memory location of the first memory zone having failed, the address of the first memory location and the address of the third memory location.

10. The method according to claim 9, wherein a read operation in the first memory zone of the one-time programmable memory comprises:
providing an address;
searching the provided address in the further memory;
in the case where the provided address is not present in the further memory, reading the digital data stored in the memory location of the first memory zone at the provided address; and
in the case where the provided address is present in the further memory, reading the digital data stored in the third memory location of the second memory zone.

11. A method for controlling a one-time programmable memory that includes a first memory zone of memory locations, a second memory zone of memory locations, and a third memory zone of memory locations, the method comprising:
arranging the second memory zone to include a plurality of first groups, each first group having a same number of consecutive memory locations;
arranging the third memory zone to include a plurality of second groups, each second group having said same number of consecutive memory locations; and
in response to a failure of a read operation of digital data in a first memory location of the first memory zone:
writing the digital data in a second memory location of the second memory zone, wherein the second memory location is located in the k-th first group of the plurality of first groups; and
writing, in a third memory location of the third memory zone, the address of the first memory location and an identifier of the second memory location, wherein the third memory location is located in the k-th second group of the plurality of second groups; and
wherein the identifier of the second memory location is equal to a rank of the second memory location in the k-th first group.

12. The method according to claim 11, wherein the rank is coded over a number of bits less than, or equal to, 4.

13. The method according to claim 11, wherein no write operation was already performed in each of the memory locations of the first group.
